(19) United States
(12) Patent Application Publication
(10) Pub. No.: US 2021/0001328 A1
(43) Pub. Date: Jan. 7, 2021

(54) SAMPLE EXTRACTING DEVICE AND RESIDUAL SOLVENT MEASURING APPARATUS INCLUDING THE SAME

(71) Applicant: SEMES Co. Ltd., Cheonan-si (KR)

(72) Inventors: Daigeon YOON, Seoul (KR); Donghwa LEE, Cheonan-si (KR); Jaeyong CHOI, Seoul (KR); Sanguk SON, Suwon-si (KR)

(73) Assignee: SEMES Co. Ltd., Cheonan-si (KR)

(21) Appl. No.: 16/920,281

(22) Filed: Jul. 2, 2020

(30) Foreign Application Priority Data
Jul. 4, 2019 (KR) 10-2019-0080492

(51) Int. Cl. B01L 3/00; B01D 11/02; G01N 1/04; G01N 1/28; G01N 1/10

(52) U.S. Cl. CPC B01L 3/502; B01D 11/0288; G01N 1/04; B01L 2400/06; G01N 1/10; B01L 2300/06; B01L 2400/0475; G01N 1/28

(57) ABSTRACT

The present invention relates to a sample extracting device and a residual solvent measuring apparatus including the same. The a residual solvent measuring apparatus of the present invention includes a sample extracting device moving on a substrate to extract a solidified sample in a liquid state on the substrate and a component analyzing unit analyzing components of the extracted sample, wherein the sample extracting device includes a coating unit coating a liquid chemical for dissolving the solidified sample on the substrate and a recovering unit recovering the liquid chemical in which the sample is dissolved on the substrate.

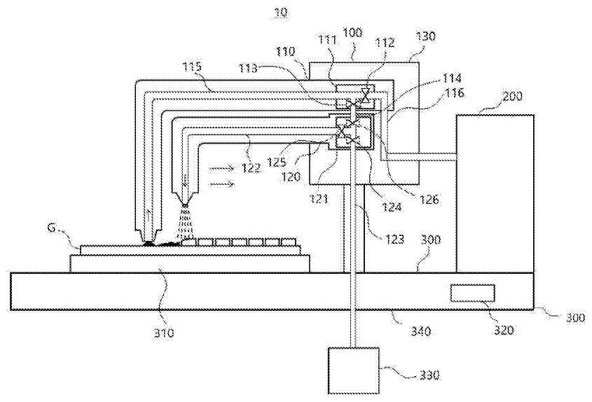

### CROSS-REFERENCE TO RELATED APPLICATION

This application claims the benefit under 35 U.S.C. 119(a) of Korean Patent Application No. 10-2019-0080492 filed on Jul. 4, 2019, in the Korean Intellectual Property Office, the entire disclosure of which is incorporated herein by reference for all purposes.

### TECHNICAL FIELD

The present invention relates to a sample extracting device and a residual solvent measuring apparatus including the same, and more particularly, to a sample extracting device which extracts a solidified sample on a substrate and a residual solvent measuring apparatus including the sample extracting device.

### BACKGROUND ART

A display process technology has developed according to a form/panel, and a new paradigm is beginning through a current maturity period. A display starts from a liquid crystal display (LCD), and has evolved into a quantum doT display and a flexible OLED through an organic light emitting display (OLED), and accordingly, a conventional process technology for manufacturing displays is converted to a new process technology.

In particular, organic chemical deposition performed in the display manufacturing process tends to be converted from a conventional heating vacuum deposition method to a pixel printing method. The pixel printing method may improve productivity by shortening a process time compared to the conventional heating vacuum deposition method.

However, according to the pixel printing method, when pixels are printed by an inkjet printing method, a volatile solvent such as a solvent remains in the printed pixels to some extent.

A volatile residual solvent such as a solvent in the printed pixels deteriorates the efficiency of a final OLED display panel, and furthermore, may cause a solvent safety problem in a product for the human body that is not currently reported.

Therefore, in order to measure components of the volatile residual solvent in the printed pixels, the components are measured using a Gel Chromatography-Mass Spectrometry (GC-MS) analysis device.

The GC-MS analysis device ionizes a sample by plasma/heat, separates the ionized sample through a membrane, moves the separated sample to a mass spectrometer having a database, and then searches and detects a molecular weight thereof.

On the other hand, since the GC-MS analysis device can basically measure a sample in a liquid form, a process of re-extracting ink solidified in a film form into a liquid is required.

In the related art, after an operator collects a solidified sample on a substrate, the operator dissolves the collected solidified sample in a solvent, concentrates the dissolved sample, and then inputs the sample to a GC-MS analyzer to measure components of the residual solvent.

However, since all the processes are performed by the operator, many works for the measurement of the residual solvent are required, and foreign substances may be introduced in the sample collection process, making it easy to measure incorrectly the components in the GC-MS analyzer.

### DISCLOSURE

### Technical Problem

An object of the present invention is to provide a sample extracting device and a residual solvent measuring apparatus including the sample extracting device capable of collecting a solidified sample and concentrating the solidified sample without operator's intervention.

### Technical Solution

To solve the problems, according to the present invention, a sample extracting device for moving on a substrate and extracting a solidified sample includes a coating unit coating a liquid chemical for dissolving the solidified sample on the substrate; and a recovering unit recovering the liquid chemical in which the sample is dissolved on the substrate.

Further, in the embodiment, the sample extracting device may further include a liquid chemical circulation line connecting the coating unit and the recovering unit, wherein the coating unit may receive the liquid chemical in which the sample is dissolved from the recovering unit through the liquid chemical circulation line and coat the liquid chemical in which the sample is dissolved on the substrate.

Further, in the embodiment, the recovering unit may include a liquid chemical recovery pump, which is connected with a liquid chemical recovery line, for recovering the liquid chemical in which the sample is dissolved, and the coating unit may include liquid chemical ejection pump for ejecting the liquid chemical on a substrate, and until the sample extraction is completed, the liquid chemical recovery pump may supply the recovered liquid chemical in which the sample is dissolved to the liquid chemical ejection pump of the coating unit.

Further, in the embodiment, a first liquid chemical circulation line valve may be provided for selectively blocking, the supply of the liquid chemical in which the sample is dissolved, from the liquid chemical recovery pump to the liquid chemical ejection pump, the first liquid chemical circulation line valve may open when the liquid chemical recovery pump recovers the liquid chemical in which the sample is dissolved, and closes when the collection of the sample is completed.

Further, in the embodiment, the liquid chemical ejection pump may include a liquid chemical ejection line valve for selectively blocking the liquid chemical ejected through the liquid chemical ejection line, and the liquid chemical ejection line valve opens while the sample is extracted and closes when the sample extraction is completed.

Further, in the embodiment, a liquid chemical supply line supplying the liquid chemical may be connected to the coating unit, a liquid chemical supply line valve may be provided in the coating unit to selectively block the liquid chemical supplied through the liquid chemical supply line, and when the coating unit receives the liquid chemical in which the sample is dissolved through the liquid chemical circulation line, the liquid chemical supply line valve may be closed or finely opened.

Further, in the embodiment, a liquid chemical output line may be provided in the recovering unit to connect a component analyzing device for analyzing components of the residual solvent, a liquid chemical output line valve may be provided in the recovering unit to selectively block the supply to the component analyzing device of the liquid chemical in which the sample is dissolved, and the liquid chemical output line valve may be closed until the sample recovery is completed.

Further, in the embodiment, a recovered liquid chemical in which the sample is dissolved may be output to the component analyzing device in a concentrated state.

Further, in the embodiment, the coating unit and the recovering unit may be disposed adjacent to each other.

According to the present invention, there is provided a residual solvent measuring apparatus including a sample extracting device extracting a sample on a substrate; and a component analyzing device analyzing components of the extracted sample, the sample extracting device comprises a coating unit configured to coat a liquid chemical for dissolving a solidified sample on the substrate; and a recovering unit configured to recover the liquid chemical in which the sample is dissolved on the substrate.

Further, in the embodiment, the sample extracting device may further include a liquid chemical circulation line connecting the coating unit and the recovering unit, wherein the coating unit may receive the liquid chemical in which the sample is dissolved from the recovering unit through the liquid chemical circulation line and coat the liquid chemical in which the sample is dissolved on the substrate.

Further, in the embodiment, the recovering unit may include a liquid chemical recovery pump, which is connected with a liquid chemical recovery line, for recovering the liquid chemical in which the sample is dissolved, and the coating unit may include liquid chemical ejection pump for ejecting the liquid chemical on a substrate, and until the sample extraction is completed, the liquid chemical recovery pump may supply the recovered liquid chemical in which the sample is dissolved to the liquid chemical ejection pump of the coating unit.

Further, in the embodiment, a first liquid chemical circulation line valve may be provided for selectively blocking, the supply of the liquid chemical in which the sample is dissolved, from the liquid chemical recovery pump to the liquid chemical ejection pump, the first liquid chemical circulation line valve may open when the liquid chemical recovery pump recovers the liquid chemical in which the sample is dissolved, and closes when the collection of the sample is completed.

Further, in the embodiment, the liquid chemical ejection pump may include a liquid chemical ejection line valve for selectively blocking the liquid chemical ejected through the liquid chemical ejection line, and the liquid chemical ejection line valve opens while the sample is extracted and closes when the sample extraction is completed.

Further, in the embodiment, a liquid chemical supply line supplying the liquid chemical may be connected to the coating unit, a liquid chemical supply line valve may be provided in the coating unit to selectively block the liquid chemical supplied through the liquid chemical supply line, and when the coating unit receives the liquid chemical in which the sample is dissolved through the liquid chemical circulation line, the liquid chemical supply line valve may be closed or finely opened.

Further, in the embodiment, a liquid chemical output line may be provided in the recovering unit to connect a component analyzing device for analyzing components of the residual solvent, a liquid chemical output line valve may be provided in the recovering unit to selectively block the supply to the component analyzing device of the liquid chemical in which the sample is dissolved, and the liquid chemical output line valve may be closed until the sample recovery is completed.

Further, in the embodiment, a recovered liquid chemical in which the sample is dissolved may be output to the component analyzing device in a concentrated state.

Further, in the embodiment, the coating unit and the recovering unit may be disposed adjacent to each other.

### Advantageous Effects

According to the present invention, the coating unit and the recovering unit are disposed close to each other on the substrate, thereby increasing a recovery rate of the ejected liquid chemical.

According to the present invention, the liquid chemical in which the sample is dissolved which is recovered from the recovering unit is supplied to the coating unit and the liquid chemical in which the sample is dissolved is recycled, thereby increasing the concentration of the sample dissolved in the liquid chemical.

### DESCRIPTION OF DRAWINGS

The FIGURE is a view illustrating a residual solvent measuring apparatus according to an embodiment of the present invention.

### MODES OF THE INVENTION

Hereinafter, a sample extracting device and a residual solvent measuring apparatus including the sample extracting device according to an embodiment of the present invention will be described with reference to the accompanying drawings. The parts required for understanding the operations and functions according to the present invention will be mainly described in detail.

In addition, in describing components of the present invention, different reference numerals may also be assigned to components having the same name according to the drawings, and the same reference numerals may be assigned in spits of different drawings. However, even in such a case, it is meant that the corresponding components have different functions according to embodiments, or it is not meant that the corresponding components have the same functions in different embodiments, and the function of each component will be determined based on the description of each component in the corresponding embodiment.

The FIGURE is a view illustrating a residual solvent measuring apparatus according to an embodiment of the present invention.

The FIGURE has illustrated the residual solvent measuring apparatus provided with the sample extracting device, but the sample extracting device of the present invention may be provided separately from the residual solvent measuring apparatus rather than the residual solvent measuring apparatus, and thus, the sample extracting device is not necessarily limited to a configuration connected to the residual solvent measuring apparatus.

Referring to The FIGURE, the residual solvent measuring apparatus 10 includes a sample extracting device 100, a component analyzing device 200, and a body 300.

The sample extracting device 100 may be used to extract a thin film sample that has become a solid during a printing process using a solvent, a process after the printing process.

The sample extracting device 100 moves on the substrate and extracts the solidified sample on the substrate in a liquid state. The sample extracting device 100 may extract the sample from the entire area on the substrate, or may extract the sample within a predetermined range.

The sample extracting device 100 includes a coating unit 120 ejecting a liquid chemical capable of dissolving the solidified sample on the substrate, a recovering unit 110 recovering the liquid chemical ejected on the substrate and in which the sample is dissolved, and a sample extracting device body 130 supporting the coating unit 120 and the recovering unit 110.

The coating unit 120 and the recovering unit 110 are disposed adjacent to each other on the substrate or disposed close to each other on the substrate.

According to the present invention, since the coating unit and the recovering unit are located close to each other on the substrate, it is possible to increase the recovery rate of the ejected liquid chemical as compared with when the recovering unit does not exist or is disposed below the substrate.

The FIGURE, the recovering unit 110 and the coating unit 120 are illustrated in the form of a nozzle, but the shapes of the recovering unit 110 and the coating unit 120 are not limited thereto.

The recovering unit 110 includes a liquid chemical recovery pump 111 for recovering the liquid chemical in which the sample is dissolved. The liquid chemical recovery pump 111 is connected with a liquid chemical recovery line 115, a liquid chemical output line 116, and a liquid chemical circulation line 114.

The liquid chemical recovery pump 111 is connected with the liquid chemical recovery line 115 to recover the liquid chemical in which the sample is dissolved through the liquid chemical recovery line 115 on the substrate.

The liquid chemical recovery pump 111 is connected with a liquid chemical ejection pump 121 through the liquid chemical circulation line 114. Until the sample extraction is completed, the liquid chemical recovery pump 111 of the recovering unit 110 supplies the recovered liquid chemical in which the sample is dissolved to the liquid chemical ejection pump 121 of the coating unit 120.

The liquid chemical recovery pump 111 includes a first liquid chemical circulation line valve 113 for selectively blocking the supply of the liquid chemical in which the sample is dissolved by the liquid chemical ejection pump 121.

The first liquid chemical circulation line valve 113 may be opened when the liquid chemical recovery pump 111 recovers the liquid chemical in which the sample is dissolved, or may be left open from the beginning. The first liquid chemical circulation line valve 113 is closed when the collection of the sample is completed.

When the collection of the sample is completed, the first liquid chemical circulation line valve 113 is closed and the liquid chemical output line valve 112 is opened. Accordingly, the recovered liquid chemical in which the sample is dissolved is output to the component analyzing device 200 in a concentrated state.

The liquid chemical recovery pump 111 is connected with the component analyzing device 200 through the liquid chemical output line 116. When sample extraction is completed, the liquid chemical recovery pump 111 supplies the recovered liquid chemical in which the sample is dissolved to the component analyzing device 200 through the liquid chemical output line 116.

The liquid chemical recovery pump 111 includes the liquid chemical output line valve 112 for supplying or blocking the recovered liquid chemical in which the sample is dissolved to the component analyzing device 200. The liquid chemical output line valve 112 is closed until the sample recovery is completed and opened when the sample recovery is completed.

The coating unit 120 includes the liquid chemical ejection pump 121 for receiving and ejecting the liquid chemical. The liquid chemical ejection pump 121 is connected with a liquid chemical supply line 123, a liquid chemical ejection line 122, and a liquid chemical circulation line 114.

The liquid chemical ejection pump 121 is connected with a liquid chemical supply source 330 through the liquid chemical supply line 123. The liquid chemical ejection pump 121 receives the liquid chemical from the liquid chemical supply source 330 through the liquid chemical supply line 123.

The liquid chemical ejection pump 121 includes a liquid chemical supply line valve 124 for selectively blocking the liquid chemical supplied through the liquid chemical supply line 123.

The liquid chemical supply line valve 124 may be opened until the liquid chemical in which the sample is dissolved is initially recovered and may be closed or finely opened when the liquid chemical in which the sample is dissolved is recovered.

When the liquid chemical in which the sample is dissolved is initially recovered, the recovered liquid chemical in which the sample is dissolved is supplied to the liquid chemical ejection pump 121 through the liquid chemical circulation line 114. Accordingly, the liquid chemical ejection pump 121 ejects the recovered liquid chemical in which the sample is dissolved on the substrate. At this time, when a supply amount of the recovered liquid chemical in which the sample is dissolved which flows into the liquid chemical ejection pump 121 is less than an ejection amount ejected from the liquid chemical ejection pump 121, in order to additionally receive the liquid chemical from the liquid chemical supply source 330, the liquid chemical supply line valve 124 may be opened finely.

According to the present invention, the liquid chemical in which the sample is dissolved which is recovered from the recovering unit is provided to the coating unit and the liquid chemical in which the sample is dissolved is coated onto the substrate again to dissolve the sample, and thus, a sample concentration in the recovered liquid chemical in which the sample is dissolved may be finally made at a high concentration.

The liquid chemical ejection pump 121 is connected to the liquid chemical ejection line 122 to eject the liquid chemical on the substrate through the liquid chemical ejection line 122.

The liquid chemical ejection pump 121 includes a liquid chemical ejection line valve 125 for selectively blocking the liquid chemical ejected through the liquid chemical ejection line 122.

The liquid chemical ejection line valve 125 opens while the sample is extracted and closes when the sample extraction is completed.

The liquid chemical ejection pump 121 is connected with the liquid chemical recovery pump 111 through the liquid chemical circulation line 114. The liquid chemical ejection pump 121 receives the liquid chemical in which the sample is dissolved which has been recovered from the liquid chemical recovery pump 111 through the liquid chemical circulation line 114.

The liquid chemical ejection pump 121 includes a second liquid chemical circulation line valve 126 for selectively blocking the supply of the liquid chemical in which the sample is dissolved from the liquid chemical recovery pump 111.

The second liquid chemical circulation line valve 126 opens or closes in conjugation with the first liquid chemical circulation line valve 113. The second liquid chemical circulation line valve 126 may open when the liquid chemical recovery pump 111 initially recovers the liquid chemical in which the sample is dissolved, or may be in an opened state from the beginning. The second liquid chemical circulation line valve 126 is closed when the collection of the sample is completed.

The liquid chemical ejection pump 121 ejects the liquid chemical in which the sample is dissolved which is received from the liquid chemical ejection pump 121 of the recovering unit 110 on the substrate.

At this time, the liquid chemical ejection pump 121 opens the second liquid chemical circulation line valve 126 to receive the liquid chemical in which the sample is dissolved from the liquid chemical recovery pump 111 through the liquid chemical circulation line 114, and closes or finely opens the liquid chemical supply line valve 124 of the liquid chemical ejection pump 121 to block the supply of the liquid chemical provided from the liquid chemical supply source 330 or receive the liquid chemical in a trace amount.

The sample extracting device body 130 is connected to a driver 340 to support the recovering unit 110 and the coating unit 120. The sample extracting device body 130 is moved according to the driving of the driver 340, and the recovering unit 110 and the coating unit 120 mounted on the sample extracting device body 130 may also be moved on the substrate.

The sample extracting device 100 may be provided in the residual solvent measuring apparatus, or may be located in a maintenance device of a substrate processing apparatus, such as an inkjet facility, or may also be configured as a separate chamber in the substrate processing apparatus.

The component analyzing device 200 receives the liquid chemical in which the sample is dissolved, and detects the components of the residual solvent. The component analyzing device 200 may include a gel chromatography-mass spectrometry (GC-MS) analysis device.

The GC-MS analysis device uses a method of ionizing the extracted sample by plasma/heat, separating the ionized sample through a membrane, moving the separated sample to a mass spectrometer having a database, and then searching and determining a molecular weight thereof.

The body 300 includes a stage 310 mounting the substrate, a controller 320 controlling the stage and the sample extracting device, a liquid chemical supply source 330 for supplying the liquid chemical to the coating unit, and a driver 340 moving a sample controller on the substrate.

The controller 320 controls the driver 340 to control the sample extracting device 100 to move on the substrate and extract the sample. Alternatively, the controller 320 may also control the driver 340 to move the stage 310 on which the substrate is mounted.

Further, the controller 320 controls the sample extracting device 100 to extract the solidified sample on the substrate by controlling the liquid chemical recovery pump 111, the liquid chemical ejection pump 121, the liquid chemical output line valve 112, the first liquid chemical circulation line valve 113, the liquid chemical supply line valve 124, the liquid chemical ejection line valve 125, and the second liquid chemical circulation line valve 126 in the sample extracting device 100.

According to the present invention, the coating unit and the recovering unit are disposed close to each other on the substrate, thereby increasing a recovery rate of the ejected liquid chemical.

According to the present invention, the liquid chemical in which the sample is dissolved which is recovered from the recovering unit is supplied to the coating unit and the liquid chemical in which the sample is dissolved is recycled, thereby increasing the concentration of the sample dissolved in the liquid chemical.

The aforementioned contents can be corrected and modified by those skilled in the art without departing from the essential characteristics of the present invention.

Therefore, the various embodiments disclosed in the present invention are not intended to limit the technical spirit but describe the present invention and the technical spirit of the present invention is not limited by the following embodiments.

The protective scope of the present invention should be construed based on the appended claims, and all the technical spirits in the equivalent scope thereof should be construed as falling within the scope of the present invention.

[Explanation of Reference Numerals and Symbols]

| | |
|---|---|
| 10: Residual solvent measuring apparatus | 100: Sample extracting device |
| 110: Recovering unit | 111: Liquid chemical recovery pump |
| 112: Liquid chemical output line valve | 113: First liquid chemical circulation line valve |
| 114: Liquid chemical circulation line | 115: Liquid chemical recovery line |
| 116: Liquid chemical output line | 120: Coating unit |
| 121: Liquid chemical ejection pump | 122: Liquid chemical ejection line |
| 123: Liquid chemical supply line | 124: Liquid chemical supply line valve |
| 125: Liquid chemical ejection line valve | 126: Second liquid chemical circulation line valve |
| 130: Sample extracting device body | 200: Component analyzing device |
| 310: Stage | 320: Controller |
| 330: Liquid chemical supply source | 340: Driver |

1. A sample extracting device for moving on a substrate and extracting a solidified sample, the sample extracting device comprising:
a coating unit configured to coat a liquid chemical for dissolving the solidified sample on the substrate; and
a recovering unit configured to recover the liquid chemical in which the sample is dissolved on the substrate.

2. The sample extracting device of claim 1, further comprising:
a liquid chemical circulation line connecting the coating unit and the recovering unit,
wherein the coating unit receives the liquid chemical in which the sample is dissolved from the recovering unit through the liquid chemical circulation line and coats the liquid chemical in which the sample is dissolved on the substrate.

3. The sample extracting device of claim 2, wherein the recovering unit includes a liquid chemical recovery pump for recovering the liquid chemical in which the sample is dissolved,
the coating unit includes liquid chemical ejection pump for ejecting the liquid chemical on a substrate, and
until the sample extraction is completed, the liquid chemical recovery pump supplies the recovered liquid chemical in which the sample is dissolved to the liquid chemical ejection pump of the coating unit.

4. The sample extracting device of claim 3, wherein a first liquid chemical circulation line valve is provided for selectively blocking, the supply of the liquid chemical in which the sample is dissolved, from the liquid chemical recovery pump to the liquid chemical ejection pump,
the first liquid chemical circulation line valve opens when the liquid chemical recovery pump recovers the liquid chemical in which the sample is dissolved, and closes when the collection of the sample is completed.

5. The sample extracting device of claim 3, wherein the liquid chemical ejection pump includes a liquid chemical ejection line valve for selectively blocking the liquid chemical ejected through a liquid chemical ejection line, and
the liquid chemical ejection line valve opens while the sample is extracted and closes when the sample extraction is completed.

6. The sample extracting device of claim 2, wherein a liquid chemical supply line supplying the liquid chemical is connected to the coating unit,
a liquid chemical supply line valve is provided in the coating unit to selectively block the liquid chemical supplied through the liquid chemical supply line, and
when the coating unit receives the liquid chemical in which the sample is dissolved through the liquid chemical circulation line, the liquid chemical supply line valve is closed or finely opened.

7. The sample extracting device of claim 6, wherein a liquid chemical output line is provided in the recovering unit to connect a component analyzing device for analyzing components of the residual solvent,
a liquid chemical output line valve is provided in the recovering unit to selectively block the supply to the component analyzing device of the liquid chemical in which the sample is dissolved, and
the liquid chemical output line valve is closed until the sample recovery is completed.

8. The sample extracting device of claim 7, wherein a recovered liquid chemical in which the sample is dissolved is output to the component analyzing device in a concentrated state.

9. The sample extracting device of claim 3, wherein the liquid chemical ejection pump includes a second liquid chemical circulation line valve for selectively blocking the supply of the liquid chemical in which the sample is dissolved, and
the second liquid chemical circulation line valve opens when the liquid chemical recovery pump recovers the liquid chemical in which the sample is dissolved

10. The sample extracting device of claim 1, wherein the coating unit and the recovering unit are disposed adjacent to each other.

11. A residual solvent measuring apparatus comprising:
a sample extracting device configured to extract a sample on a substrate; and
a component analyzing device configured to analyze components of the extracted sample,
wherein the sample extracting device comprises
a coating unit configured to coat a liquid chemical for dissolving a solidified sample on the substrate; and
a recovering unit configured to recover the liquid chemical in which the sample is dissolved on the substrate.

12. The residual solvent measuring apparatus of claim 11, further comprising:
a liquid chemical circulation line connecting the coating unit and the recovering unit,
wherein the coating unit receives the liquid chemical in which the sample is dissolved from the recovering unit through the liquid chemical circulation line and coats the liquid chemical in which the sample is dissolved on the substrate.

13. The residual solvent measuring apparatus of claim 12,
wherein the recovering unit includes a liquid chemical recovery pump for recovering the liquid chemical in which the sample is dissolved,
the coating unit includes liquid chemical ejection pump for ejecting the liquid chemical on a substrate, and
until the sample extraction is completed, the liquid chemical recovery pump supplies the recovered liquid chemical in which the sample is dissolved to the liquid chemical ejection pump of the coating unit.

14. The residual solvent measuring apparatus of claim 13,
wherein a first liquid chemical circulation line valve is provided for selectively blocking, the supply of the liquid chemical in which the sample is dissolved, from the liquid chemical recovery pump to the liquid chemical ejection pump,
the first liquid chemical circulation line valve opens when the liquid chemical recovery pump recovers the liquid chemical in which the sample is dissolved, and closes when the collection of the sample is completed.

15. The residual solvent measuring apparatus of claim 13, wherein the liquid chemical ejection pump includes a liquid chemical ejection line valve for selectively blocking the liquid chemical ejected through a liquid chemical ejection line, and
the liquid chemical ejection line valve opens while the sample is extracted and closes when the sample extraction is completed.

16. The residual solvent measuring apparatus of claim 12, wherein a liquid chemical supply line supplying the liquid chemical is connected to the coating unit,
a liquid chemical supply line valve is provided in the coating unit to selectively block the liquid chemical supplied through the liquid chemical supply line, and
when the coating unit receives the liquid chemical in which the sample is dissolved through the liquid chemical circulation line, the liquid chemical supply line valve is closed or finely opened.

17. The residual solvent measuring apparatus of claim 16, wherein a liquid chemical output line is provided in the recovering unit to connect a component analyzing device for analyzing components of the residual solvent,
a liquid chemical output line valve is provided in the recovering unit to selectively block the supply to the component analyzing device of the liquid chemical in which the sample is dissolved, and
the liquid chemical output line valve is closed until the sample recovery is completed.

18. The residual solvent measuring apparatus of claim 17, wherein a recovered liquid chemical in which the sample is dissolved is output to the component analyzing device in a concentrated state.

19. The residual solvent measuring apparatus of claim 13, wherein the liquid chemical ejection pump includes a second liquid chemical circulation line valve for selectively blocking the supply of the liquid chemical in which the sample is dissolved, and
the second liquid chemical circulation line valve opens when the liquid chemical recovery pump recovers the liquid chemical in which the sample is dissolved.

20. The residual solvent measuring apparatus of claim 11, wherein the coating unit and the recovering unit are disposed adjacent to each other.
